(19) United States
(12) Patent Application Publication
(10) Pub. No.: US 2025/0203862 A1
(43) Pub. Date: Jun. 19, 2025

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventors: Eun Seok CHOI, Gyeonggi-do (KR); Dong Won KIM, Gyeonggi-do (KR); Yu Jin PARK, Gyeonggi-do (KR); Hui Woo PARK, Gyeonggi-do (KR); Young Ock HONG, Gyeonggi-do (KR)

(21) Appl. No.: 18/626,353

(22) Filed: Apr. 4, 2024

(30) Foreign Application Priority Data
Dec. 13, 2023 (KR) 10-2023-0180638

(51) Int. Cl. H10B 41/41; H01L 23/522; H01L 23/528; H10B 41/10; H10B 41/27; H10B 43/10; H10B 43/27; H10B 43/40

(52) U.S. Cl. CPC H10B 41/41; H01L 23/5226; H01L 23/5283; H10B 41/10; H10B 41/27; H10B 43/10; H10B 43/27; H10B 43/40

(57) ABSTRACT

A semiconductor device may include: a peripheral circuit located on a substrate; a stack structure located over the peripheral circuit in a non-core region and including insulating layers and dummy layers that are alternately and repeatedly stacked; a channel pattern located on the stack structure; a transistor located on the channel pattern; a contact structure extending through the stack structure and electrically connecting the peripheral circuit to the channel pattern; a gate structure located over the peripheral circuit in a core region and including insulating layers and conductive layers that are alternately and repeatedly stacked; a first source pattern located on the gate structure; and a channel structure extending through the gate structure to contact the first source pattern.

### CROSS-REFERENCE TO RELATED APPLICATION

This application claims priority under 35 U.S.C. § 119 to Korean Patent Application No. 10-2023-0180638 filed on Dec. 13, 2023, which is incorporated herein by reference in its entirety.

### BACKGROUND

### 1. Technical Field

Embodiments of the present disclosure relate to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a peripheral circuit located on a substrate; a stack structure located over the peripheral circuit in a non-core region and including insulating layers and sacrificial layers that are alternately and repeatedly stacked; a channel pattern located on the stack structure; a transistor located on the channel pattern; a contact structure extending through the stack structure and electrically connecting the peripheral circuit to the channel pattern; a gate structure located over the peripheral circuit in a core region and including insulating layers and conductive layers that are alternately and repeatedly stacked; a first source pattern located on the gate structure; and a channel structure extending through the gate structure to contact the first source pattern.

In an embodiment, a semiconductor device may include: a substrate; a first transistor located on the substrate; a stack structure located over the first transistor in a non-core region and including insulating layers and dummy layers that are alternately and repeatedly stacked; a single crystal silicon pattern located on the stack structure; a second transistor located on the single crystal silicon pattern; a contact structure extending through the stack structure to contact the single crystal silicon pattern; and a bonding structure located between the first transistor and the stack structure and electrically connecting the contact structure to the first transistor.

In an embodiment, a method for manufacturing a semiconductor device may include: forming a stack structure on a substrate; forming a channel structure extending through the stack structure; forming a contact structure extending through the stack structure to contact the substrate; forming a preliminary channel layer by removing a portion of the substrate so that the channel structure is exposed; forming channel patterns by patterning the preliminary channel layer; forming a conductive layer on the channel patterns; and forming gate electrodes on the channel patterns, respectively, by patterning the conductive layer.

In an embodiment, a method a for manufacturing semiconductor device may include: forming a first wafer including a first substrate, a peripheral circuit formed on the first substrate, and a first bonding pad formed on the peripheral circuit; forming a second wafer including a second substrate, a stack structure formed on the second substrate, a contact structure extending through the stack structure to contact the second substrate, a gate structure formed on the second substrate, a channel structure extending into the second substrate through the gate structure, and a second bonding pad formed on the contact structure and the channel structure; bonding the first wafer and the second wafer so that the first bonding pad and the second bonding pad are electrically connected to each other; exposing the channel structure and forming a preliminary channel layer connected to the contact structure, by partially removing the second substrate; forming channel patterns by patterning the preliminary channel layer; and forming gate electrodes on the channel patterns, respectively.

### BRIEF DESCRIPTION OF THE DRAWINGS

FIGS. 1A to 1C are diagrams for describing a semiconductor device in accordance with an embodiment of the present disclosure.

FIGS. 2A to 6B are diagrams for describing a manufacturing method of a semiconductor device in accordance with an embodiment of the present disclosure.

### DETAILED DESCRIPTION

Various embodiments are directed to a semiconductor device having a stable structure and improved characteristics and a manufacturing method of the semiconductor device.

According to embodiments of the present disclosure, it is possible to provide a semiconductor device having a stable structure and improved reliability.

Hereafter, embodiments in accordance with the technical spirit of the present disclosure will be described with reference to the accompanying drawings.

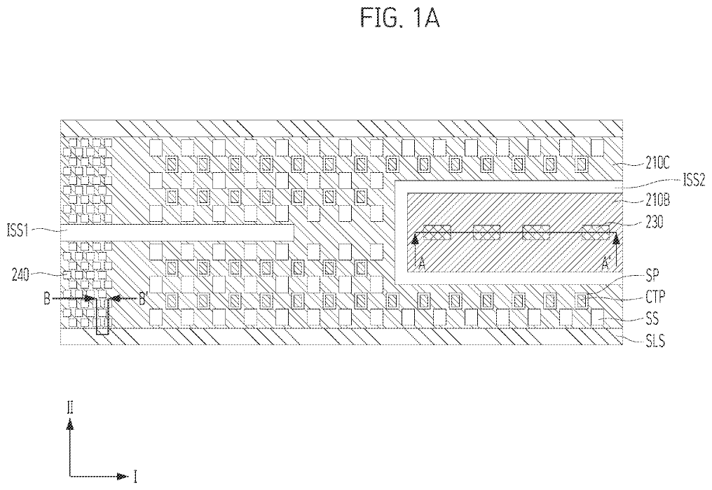

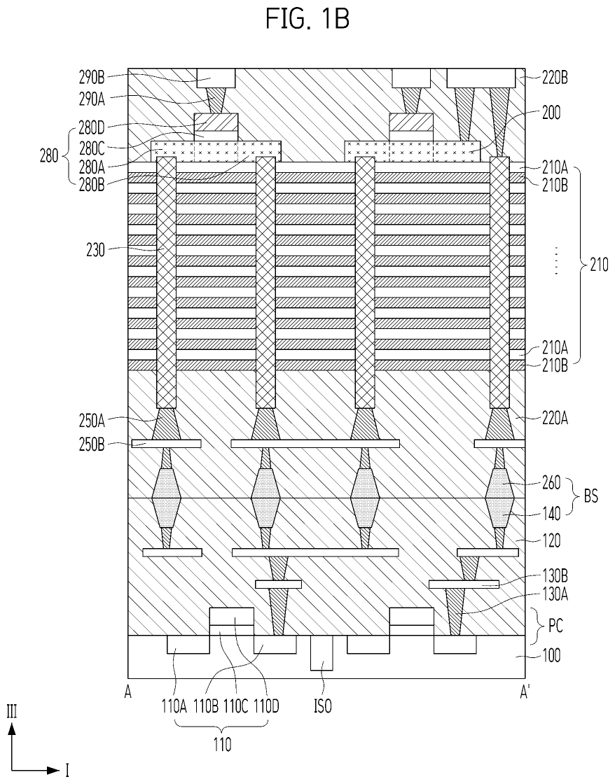

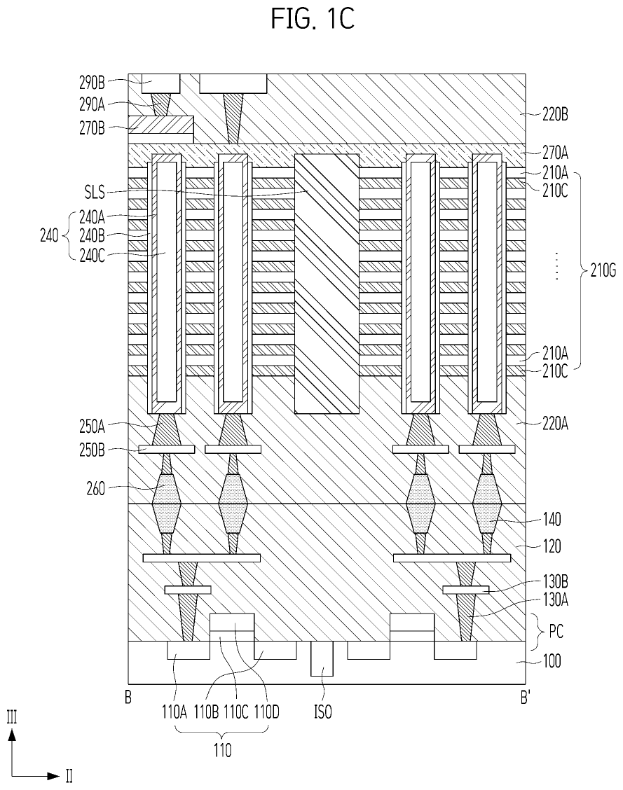

FIGS. 1A to 1C are diagrams for describing a semiconductor device in accordance with an embodiment of the present disclosure. FIG. 1A is a plan view, FIG. 1B is a cross-sectional view taken along line A-A′ of FIG. 1A, and FIG. 1C is a cross-sectional view taken along line B-B′ of FIG. 1A. FIG. 1B shows a non-core region (i.e., a peripheral circuit region) and FIG. 1C shows a core region (i.e., a cell region).

Referring to FIGS. 1A to 1C, the semiconductor device may include a substrate 100, a peripheral circuit PC, an isolation layer ISO, a first interlayer insulating layer 120, a first contact via 130A, a first wiring line 130B, a first bonding pad 140, a channel pattern 200, a stack structure 210, a gate structure 210G, a second interlayer insulating layer 220A, a third interlayer insulating layer 220B, a contact structure 230, a channel structure 240, a second contact via 250A, a second wiring line 250B, a second bonding pad 260, a first source pattern 270A, a second source pattern 270B, a third contact via 290A, a third wiring line 290B, a slit structure SLS, a support SS, an insulating spacer SP, a first isolation insulating structure ISS1, a second isolation insulating structure ISS2, and a contact plug CTP.

The peripheral circuit PC and the isolation layer ISO may be located in the substrate 100. An active region may be defined by the isolation layer ISO. The peripheral circuit PC may include at least one of a page buffer and a row decoder. The row decoder may include a first transistor 110, a capacitor, a resistor, or the like. Here, the first transistor 110 may be a pass transistor. The first transistor 110 may include at least one of a first junction 110A, a second junction 110B, a first gate insulating layer 110C, and a first gate electrode 110D. The first gate insulating layer 110C may be located between the first gate electrode 110D and the substrate 100. The first gate insulating layer 110C or the isolation layer ISO may include an insulating material, such as, oxide or nitride. The first gate electrode 110D may include at least one of polysilicon and metal.

The first interlayer insulating layer 120 may be located on the substrate 100. At least one of the first contact vias 130A and the first wiring lines 130B may be located in the first interlayer insulating layer 120. Each of the first contact vias 130A may connect at least one of the junctions 110A and 110B of the first transistor 110 to the first wiring line 130B, connect the first wiring lines 130B to each other, or connect the first wiring line 130B to the first bonding pad 140. Each of the first wiring lines 130B may be connected to the first contact via 130A or may connect the first contact vias 130A to each other. The first contact via 130A or the first wiring line 130B may include a conductive material such as tungsten.

The first bonding pads 140 may be located on the first contact vias 130A, and connected to at least one of the first contact vias 130A. The peripheral circuit PC may be electrically connected to the first bonding pads 140 through the first contact vias 130A and first wiring lines 130B.

The gate structure 210G may be located on or over the peripheral circuit PC. The gate structure 210G may include insulating layers 210A and conductive layers 210C that are alternately and repeatedly stacked. Here, the conductive layers 210C may be word lines, bit lines, or select lines. For example, the conductive layers 210C may be source select lines or drain select lines. The insulating layers 210A may each include an insulating material, such as, oxide; and the conductive layers 210C may each include a conductive material, such as, tungsten, molybdenum, or polysilicon.

The stack structure 210 may be located on or over the peripheral circuit PC, and may include insulating layers 210A and sacrificial layers 210B that are alternately and repeatedly stacked. Here, the sacrificial layers 210B may be layers remaining in the peripheral circuit region without being replaced with the conductive layers 210C during a manufacturing process for forming the gate structure 210G in the core region. That is, the sacrificial layers 210B may be a dummy layer that is not actively working as a component at least in the non-core region. The stack structure 210 may have substantially the same thickness as the gate structure 210G. The sacrificial layers 210B may each include a sacrificial material, such as, nitride.

The channel structures 240 may extend through the gate structure 210G. For example, the channel structures 240 may extend into the first source pattern 270A through the gate structure 210G. Here, the first source pattern 270A may be located on the gate structure 210G. Each of the channel structures 240 may include at least one of a channel layer 240A, a memory layer 240B, and an insulating core 240C. Here, the channel layer 240A may be connected to the first source pattern 270A. The memory layer 240B may surround the channel layer 240A; and the insulating core 240C may be located in the channel layer 240A.

The slit structure SLS may extend through the gate structure 210G. For example, the slit structure SLS may extend into the first source pattern 270A through the gate structure 210G. The slit structure SLS may be formed in a slit used as a passage for replacing the sacrificial layers 210B with the conductive layers 210C in the manufacturing process. The slit structure SLS may include at least one of an insulating material such as oxide, a conductive material, and a semiconductor material.

The supports SS may extend through the gate structure 210G. The supports SS may be arranged in a first direction I and a second direction II intersecting the first direction I. The supports SS may be used to support the stack structure 210 and the gate structure 210G. The supports SS may have various shapes. For example, the supports SS may each have a pillar shape. The supports SS may each include an insulating material, such as, oxide.

The first isolation insulating structure ISS1 may extend through the gate structure 210G. The first isolation insulating structure ISS1 may extend in the first direction I. The first isolation insulating structure ISS1 may be located between the channel structures 240. For reference, the first isolation insulating structure ISS1 may have a height at which it penetrates through the source select lines or the drain select lines among the conductive layers 210C of the gate structure 210G. The first isolation insulating structure ISS1 may include an insulating material, such as, oxide.

The second isolation insulating structure ISS2 may be located between the stack structure 210 and the gate structure 210G. The second isolation insulating structure ISS2 may be used to isolate the stack structure 210 disposed in the non-core region and the gate structure 210G disposed in the core region from each other. That is, the second isolation insulating structure ISS2 may isolate the non-core region and the core region. The second isolation insulating structure ISS2 may have various shapes. For example, the second isolation insulating structure ISS2 may have a C-shape. The second isolation insulating structure ISS2 may include an insulating material, such as, oxide.

The contact plugs CTP may extend through the gate structure 210G. Alternatively, the contact plugs CTP may be located on the gate structure 210G. Here, the gate structure 210G may have a staircase structure. The contact plugs CTP may be arranged in the first direction I and the second direction II. Each of the contact plugs CTP may be connected to at least one of the conductive layers 210C of the gate structure 210G. Here, sidewalls of the contact plugs CTP may be surrounded by the insulating spacers SP. The insulating spacer SP may include an insulating material, such as, oxide; and the contact plug CTP may include a conductive material, such as, tungsten.

The channel pattern 200 may be located on the stack structure 210. The channel pattern 200 may be a pattern remaining without being removed from a substrate material used as a support base for the stack structure 210 and the gate structure 210G in the manufacturing process. The channel pattern 200 may be a single crystal silicon pattern. A second transistor 280 may be located on the channel pattern 200. The second transistor 280 may include at least one of a third junction 280A, a fourth junction 280B, a second gate insulating layer 280C, and a second gate electrode 280D. Here, the second gate electrode 280D may be located on the channel pattern 200. Also, the third junction 280A and the fourth junction 280B may be located in the channel pattern 200. For reference, a well region for forming an N-channel metal oxide semiconductor (NMOS) transistor or a P-channel metal oxide semiconductor (PMOS) transistor may be located in the channel pattern 200. The second gate electrode 280D may include at least one of polysilicon and metal.

The second transistor 280 may have substantially the same function as the first transistor 110. For example, the second transistor 280 may be a pass transistor. However, the present disclosure is not limited thereto, and the second transistor 280 and the first transistor 110 may have different functions. When only an interconnection structure is located on the stack structure 210, an upper region of the stack structure 210 may be used only as a signal transmission region. However, according to an embodiment of the present disclosure, by locating the second transistor 280 on the stack structure 210, it is also possible to use the upper region of the stack structure 210 as a peripheral circuit region. In addition, by operating a cell array using the peripheral circuit PC and the second transistor 280, it is possible to improve the performance of the semiconductor device.

The contact structure 230 may extend through the stack structure 210. For example, the contact structure 230 may extend into the channel pattern 200 through the stack structure 210. The contact structure 230 may be connected to at least one of the junctions 280A and 280B in the channel pattern 200. The contact structure 230 may electrically connect the peripheral circuit PC to the channel pattern 200. For example, the contact structure 230 may electrically connect at least one of the junctions 280A and 280B in the channel pattern 200 and the peripheral circuit PC to each other. Accordingly, the peripheral circuit PC and the second transistor 280 may be electrically connected to each other through the contact structure 230. The contact structure 230 may include a conductive material, such as, tungsten.

The second interlayer insulating layer 220A may be located below the stack structure 210 and the gate structure 210G. At least one of the second contact vias 250A and the second wiring lines 250B may be located in the second interlayer insulating layer 220A. Each of the second contact vias 250A may connect at least one of the channel structures 240 and the second wiring line 250B to each other, connect at least one of the contact structures 230 and the second wiring line 250B to each other, or connect the second wiring line 250B and the second bonding pad 260 to each other. Each of the second wiring lines 250B may be connected to the second contact via 250A or may connect the second contact vias 250A to each other. The second contact via 250A or the second wiring line 250B may include a conductive material, such as, tungsten.

The second bonding pads 260 may be located below the second contact vias 250A, and connected to at least one of the second contact vias 250A. Consequently, a bonding structure BS electrically connecting the peripheral circuit PC and the second transistor 280 to each other may be defined. The bonding structure BS may be located between the stack structure 210 or the gate structure 210G and the peripheral circuit PC. The bonding structure BS may include the first bonding pads 140 and the second bonding pads 260. The first bonding pads 140 and the second bonding pads 260 may be electrically connected to each other.

The third interlayer insulating layer 220B may be located on the stack structure 210 and the gate structure 210G. At least one of the third contact vias 290A and the third wiring lines 290B may be located in the third interlayer insulating layer 220B. For example, the third contact via 250A may be connected to at least one of the second gate electrode 280D and the junctions 280A and 280B of the second transistor 280, the first source pattern 270A, and the second source pattern 270B. Each of the third wiring lines 290B may be connected to the third contact via 290A or may connect the third contact vias 290A to each other. For example, the third wiring line 290B may connect the third contact via 290A, which is connected to the contact structure 230, to the third contact via 290A which is connected to at least one of the junctions 280A and 280B. The third contact via 290A or the third wiring line 290B may include a conductive material, such as, tungsten.

The second source pattern 270B may be located on the first source pattern 270A. Because the second source pattern 270B may be electrically connected to the first source pattern 270A to be used as one source pattern, resistance of the source pattern may be lowered. For example, the first source pattern 270A and the second source pattern 270B may be electrically connected to each other through the third contact via 290A and the third wiring line 290B. The second source pattern 270B may be formed simultaneously with the second gate electrode 280D of the second transistor 280 when the second gate electrode 280D of the second transistor 280 is formed. Accordingly, the second source pattern 270B may have substantially the same thickness as the second gate electrode 280D. The second source pattern 270B may include at least one of polysilicon and metal.

For reference, here, the terms “above” and “below” are relative concepts for convenience of explanation. For example, the first source pattern 270A may be located below the gate structure 210G, and the channel pattern 200 may be located below the stack structure 210. Alternatively, the peripheral circuit PC may be located on the second transistor 280.

In addition, although not illustrated in FIGS. 1A to 1C, connection relationships between the contact vias 130A, 250A, and 290A and the wiring lines 130B, 250B, and 290B may be varied. For example, the connection relationships between the contact vias 130A, 250A, and 290A and the wiring lines 130B, 250B, and 290B may be varied depending on the connective relationship between the peripheral circuit PC and the second transistors 280.

According to the structure described above, by locating the second transistor 280 on the stack structure 210, it is possible to use the upper region of the stack structure 210 as the peripheral circuit region. In addition, by operating the cell array using the peripheral circuit PC and the second transistor 280, it is possible to improve the performance of the semiconductor device.

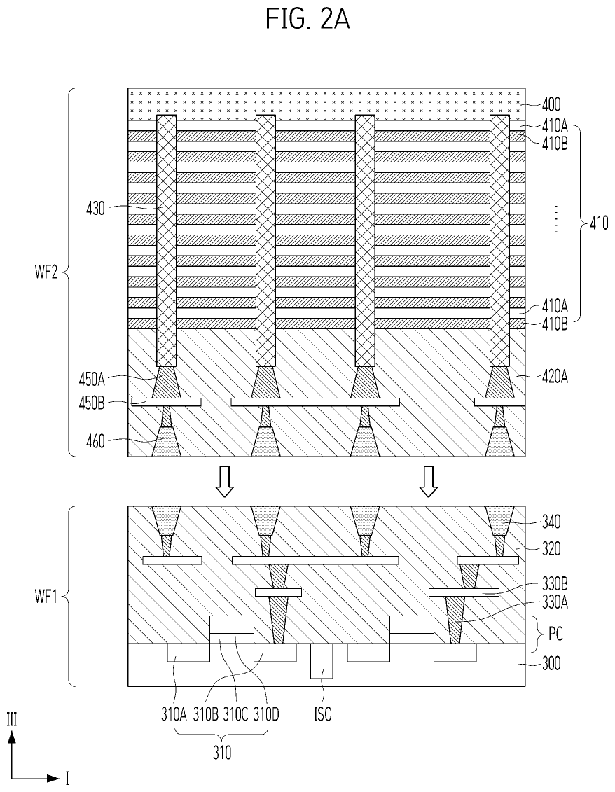

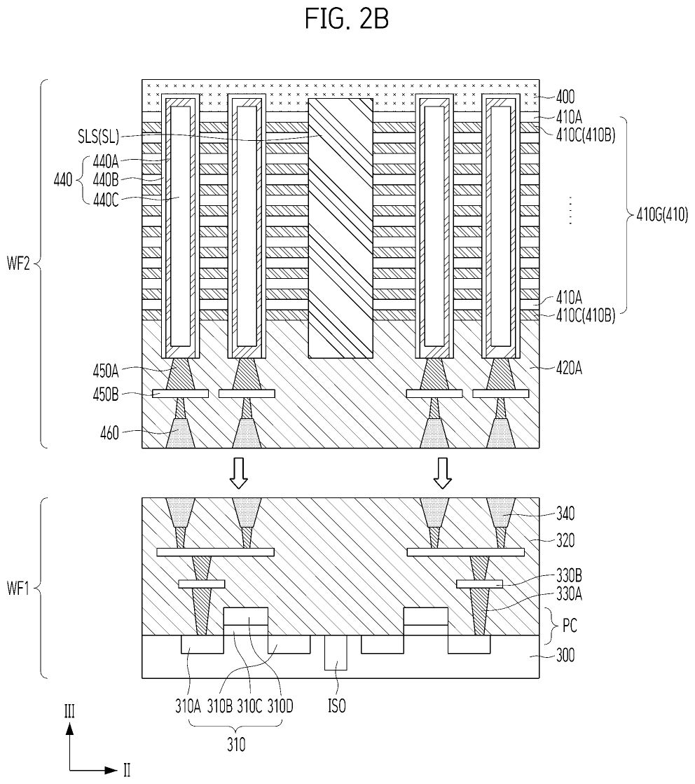

FIGS. 2A to 6B are diagrams for describing a manufacturing method of a semiconductor device in accordance with an embodiment of the present disclosure. Hereinafter, the content overlapping with the previously described content will be omitted.

Referring to FIGS. 2A and 2B, a first wafer WF1 may be formed. First, a peripheral circuit PC may be formed on a first substrate 300. An isolation layer ISO may be formed in the first substrate 300. An active region may be defined by the isolation layer ISO. The peripheral circuit PC may include at least one of a page buffer and a row decoder. The row decoder may include a first transistor 310, a capacitor, a resistor, or the like. Here, the first transistor 310 may be a pass transistor. The first transistor 310 may include at least one of a first junction 310A, a second junction 310B, a first gate insulating layer 310C, and a first gate electrode 310D. The first gate insulating layer 310C may be located between the first gate electrode 310D and the first substrate 300. The first gate insulating layer 310C or the isolation layer ISO may include an insulating material, such as, oxide or nitride. The first gate electrode 310D may include at least one of polysilicon and metal.

First bonding pads 340 may be formed on the peripheral circuit PC. First, at least one of first contact vias 330A and first wiring lines 330B may be formed on the peripheral circuit PC. Subsequently, the first bonding pads 340 may be formed over the first contact vias 330A and the first wiring lines 330B. The first contact vias 330A, the first wiring lines 330B, and the first bonding pads 340 may be formed in a first interlayer insulating layer 320. The first bonding pads 340 may be electrically connected to the peripheral circuit PC through the first contact vias 330A and the first wiring lines 330B. The first contact vias 330A, the first wiring lines 330B, and the first bonding pads 340 may each include a conductive material, such as, tungsten or copper.

Subsequently, a second wafer WF2 may be formed. First, a stack structure 410 may be formed by alternately and repeatedly stacking first material layers 410A and second material layers 410B on a second substrate 400. Here, the first material layers 410A may each include an insulating material, such as, oxide; and the second material layers 410B may each include a sacrificial material, such as, nitride. Here, the second substrate 400 may include a single crystal silicon material.

Channel structures 440 extending through the stack structure 410 may be formed. For example, the channel structures 440 extending into the second substrate 400 through the stack structure 410 may be formed. Each of the channel structures 440 may include at least one of a channel layer 440A, a memory layer 440B surrounding the channel layer 440A, and an insulating core 440C located in the channel layer 440A.

Contact structures 430 extending through the stack structure 410 may be formed. For example, the contact structures 430 extending into the second substrate 400 through the stack structure 410 may be formed. The contact structure 430 may include a conductive material, such as, tungsten.

A slit SL extending through the stack structure 410 may be formed, and the second material layers 410B may be replaced with third material layers 410C through the slit SL. Consequently, a gate structure 410G including the first material layers 410A and the third material layers 410C that are alternately and repeatedly stacked may be defined. The third material layers 410C may be word lines, bit lines, or select lines. Here, some of the second material layers 410B may remain without being replaced with the third material layers 410C.

Second bonding pads 460 may be formed on the stack structure 410 and the gate structure 410G. For example, the second bonding pads 460 may be formed on the contact structures 430 and the channel structures 440. First, at least one of second contact vias 450A and second wiring lines 450B may be formed on the contact structures 430 and the channel structures 440. Subsequently, the second bonding pads 460 may be formed on the second contact vias 450A and the second wiring lines 450B. The second contact vias 450A, the second wiring lines 450B, and the second bonding pads 460 may be formed in a second interlayer insulating layer 420A. The second bonding pads 460 may be electrically connected to the contact structures 430 or the channel structures 440 through the second contact vias 450A and the second wiring lines 450B. The second contact vias 450A, the second wiring lines 450B, and the second bonding pads 460 may each include a conductive material, such as, tungsten or copper.

Subsequently, the first wafer WF1 and the second wafer WF2 may be bonded to each other. The second wafer WF2 may be rotated and bonded to the first wafer WF1. For example, the first wafer WF1 and the second wafer WF2 may be bonded to each other so that the first bonding pads 340 of the first wafer WF1 and the second bonding pads 460 of the second wafer WF2 are electrically connected to each other.

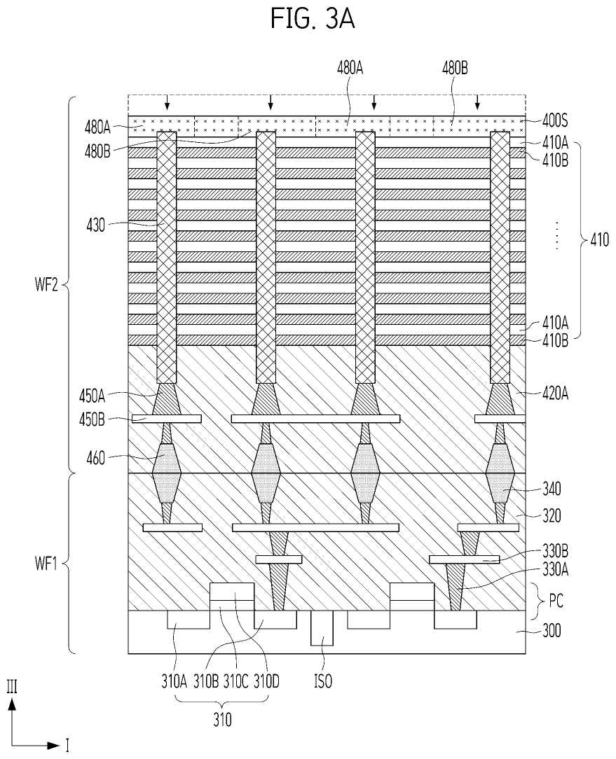

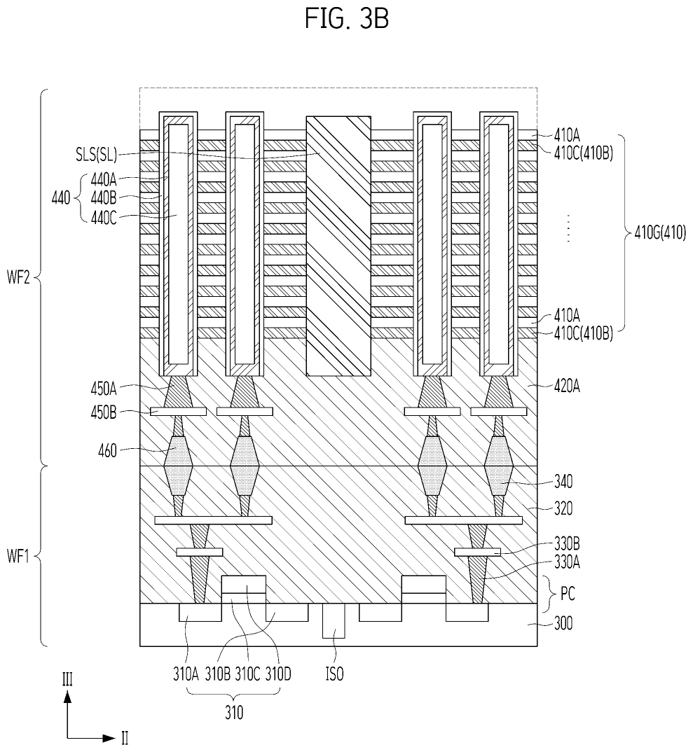

Referring to FIGS. 3A and 3B, the second substrate 400 may be partially removed. For example, the second substrate 400 may be partially removed so that the channel structures 440 are exposed. First, a rear surface of the second substrate 400 may be etched so that a thickness of the second substrate 400 is reduced. In this case, an etching thickness may be adjusted so that the channel structures 440 and the contact structures 430 are not exposed. Subsequently, the channel structures 440 may be exposed by patterning the second substrate 400. Here, the contact structures 430 may not be exposed. The second substrate 400 remaining on the contact structures 430 may be defined as a preliminary channel layer 400S.

Subsequently, third junctions 480A and fourth junctions 480B may be formed in the preliminary channel layer 400S. For example, the third junctions 480A and the fourth junctions 480B may be formed by implanting n-type or p-type impurities into the preliminary channel layer 400S. Here, the junctions 480A and 480B may be formed by implanting the n-type or p-type impurities through a rear surface of the preliminary channel layer 400S.

For reference, a well region for forming an NMOS transistor or a PMOS transistor may be formed in advance in the second substrate 400. For example, the well region may be formed in advance in the second substrate 400 before the stack structure 410 is formed. Here, the well region may be formed through a front surface of the second substrate 400.

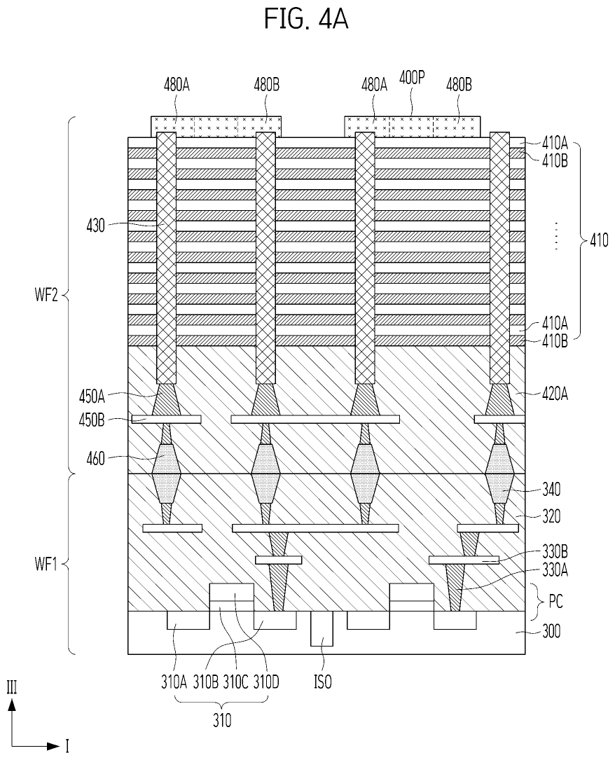

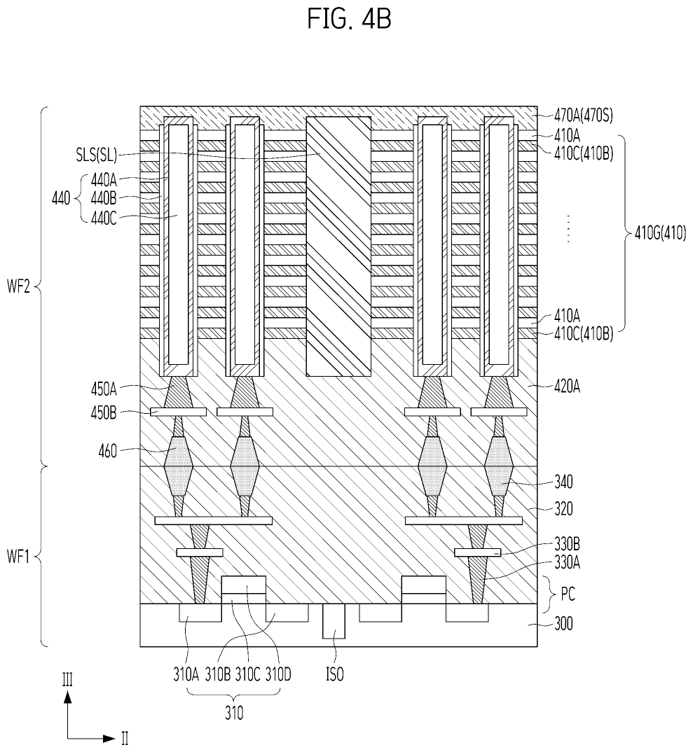

Referring to FIGS. 4A and 4B, the channel layers 440A of the channel structures 440 may be exposed. For example, the channel layers 440A of the channel structures 440 may be exposed by partially removing the memory layers 440B of the channel structures 440.

Subsequently, a source layer 470S may be formed on the preliminary channel layer 400S and the channel structures 440. The source layer 470S may be formed to cover the preliminary channel layer 400S and the channel structures 440. Subsequently, a first source pattern 470A may be formed by patterning the source layer 470S. For example, the first source pattern 470A connected to the channel structures 440 may be formed on the channel structures 440. Here, the source layer 470S may be removed on the contact structures 430. The channel layers 440A of the channel structures 440 and the first source pattern 470A may be connected to each other.

Channel patterns 400P may be formed by patterning the preliminary channel layer 400S. For example, the preliminary channel layer 400S may be patterned so that the channel patterns 400P are spaced apart from each other. Alternatively, the channel patterns 400P may be formed by forming an isolation shallow trench in the preliminary channel layer 400S. For example, isolation shallow trench may be formed to by etching the preliminary channel layer 400S to form the channel patterns 400P that are spaced apart from each other. When the source layer 470S is patterned, the channel patterns 400P may be formed by patterning the preliminary channel layer 400S. However, the present disclosure is not limited thereto, and the source layer 470S may be formed after the preliminary channel layer 400S is patterned. Alternatively, the preliminary channel layer 400S may be patterned after the source layer 470S is patterned. Here, the channel patterns 400P are formed from the second substrate 400P that remains, and may thus be single crystal silicon patterns.

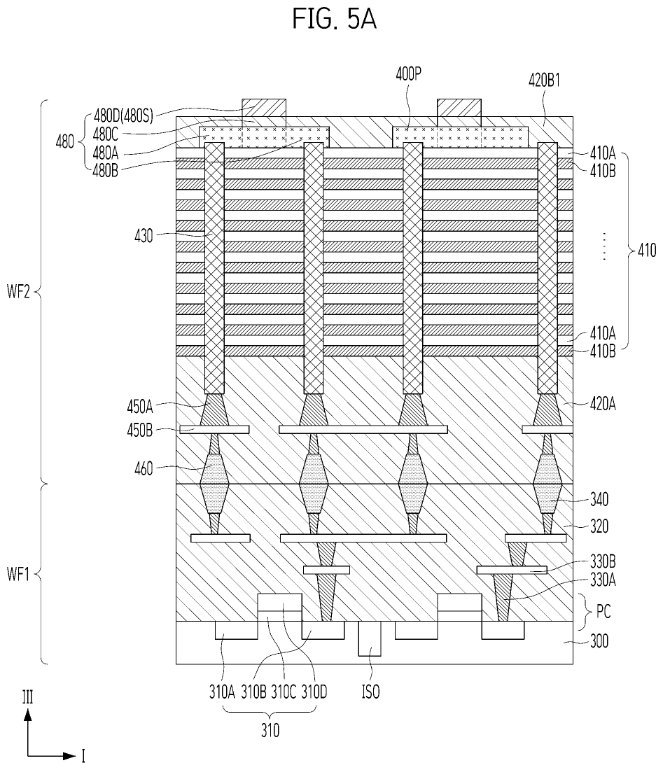

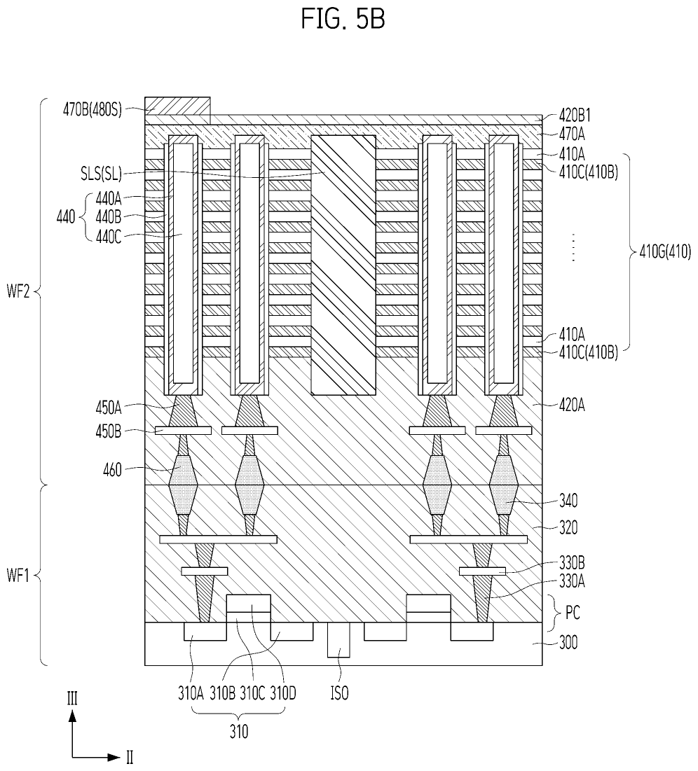

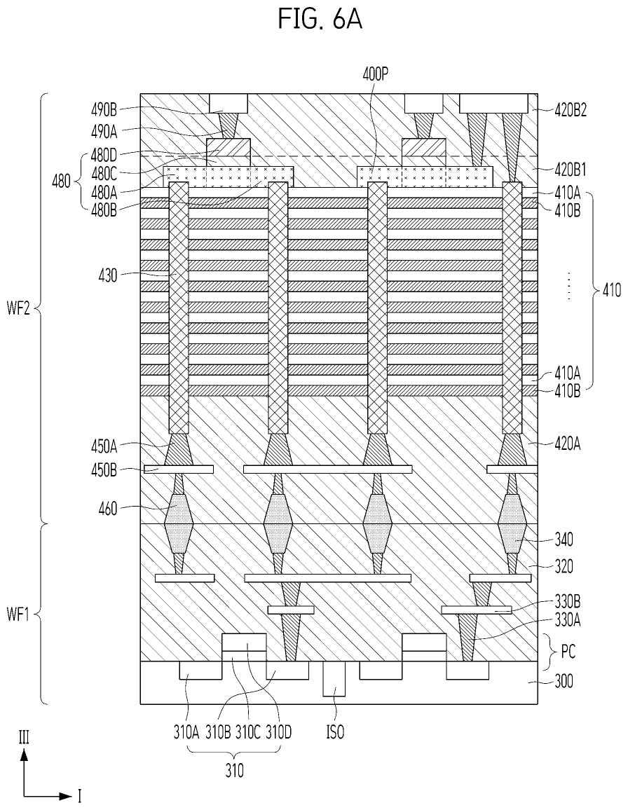

Referring to FIGS. 5A and 5B, a second transistor 480 may be formed. First, a third interlayer insulating layer 420B1 may be formed on the channel patterns 400P and the first source pattern 470A. The third interlayer insulating layer 420B1 may include an insulating material, such as, oxide. Subsequently, the third interlayer insulating layer 420B1 may be partially etched. For example, the third interlayer insulating layer 420B1 may be planarized. An etching thickness may be adjusted so that the channel patterns 400P and the first source pattern 470A are not exposed. Subsequently, a conductive layer 480S may be formed on the channel patterns 400P and the first source pattern 470A. Here, the conductive layer 480S may include at least one of polysilicon and metal. Subsequently, second gate electrodes 480D may be formed by patterning the conductive layer 480S. The second gate electrodes 480D may be formed on the channel patterns 400P, respectively. A portion of the third interlayer insulating layer 420B1 located between the channel pattern 400P and the second gate electrode 480D may be used as a second gate insulating layer 480C. Consequently, the second transistor 480 including the junctions 480A and 480B, the second gate insulating layer 480C, and the second gate electrode 480D may be formed.

The second transistor 480 may have substantially the same function as the first transistor 310. For example, the second transistor 480 may be a pass transistor. However, the present disclosure is not limited thereto, and the second transistor 480 and the first transistor 310 may have different functions.

A second source pattern 470B may be formed on the first source pattern 470A by patterning the conductive layer 480S. The second source pattern 470B may be formed when the second gate electrodes 480D are formed. Accordingly, the second source pattern 470B may include at least one of polysilicon and metal. Because the second source pattern 470B may be electrically connected to the first source pattern 470A to be used as one source pattern, resistance of the source pattern may be lowered.

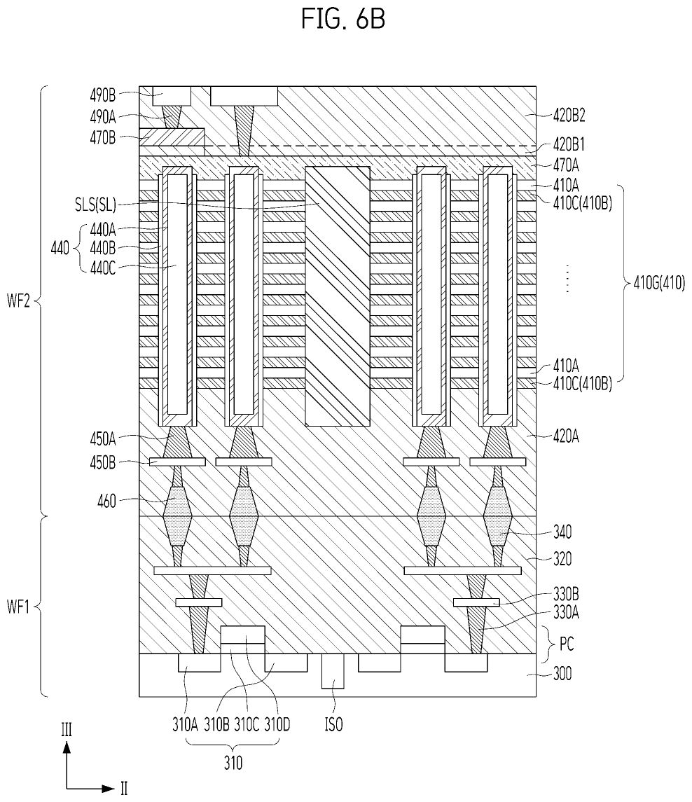

Referring to FIGS. 6A and 6B, at least one of third contact vias 490A and third wiring lines 490B may be formed. For example, the third contact vias 490A connected to at least one of the gate electrodes 480D, the junctions 480A and 480B, the first source pattern 470A, and the second source pattern 470B may be formed. The third contact vias 490A and the third wiring lines 490B may be formed in a fourth interlayer insulating layer 420B2. Here, the fourth interlayer insulating layer 420B2 may be formed on the third interlayer insulating layer 420B1. Each of the third wiring lines 490B may be connected to the third contact via 490A or may connect the third contact vias 490A to each other. For example, the third wiring line 490B may connect the third contact via 490A, which is connected to the contact structure 430, to the third contact via 490A which is connected to at least one of the junctions 480A and 480B. The third contact via 490A or the third wiring line 490B may include a conductive material, such as, tungsten.

When only an interconnection structure including the third contact vias 490A and the third wiring lines 490B is located on the stack structure 410, an upper region of the stack structure 410 may be used only as a signal transmission region. However, according to an embodiment of the present disclosure, by forming the second transistor 480 on the stack structure 410, it is possible to use the upper region of the stack structure 410 as a peripheral circuit region.

According to the manufacturing method described above, it is possible to form the channel pattern 400P of the second transistor 480 by removing a portion of the second substrate 400. By forming the second transistor 480 on the stack structure 410, it is possible to use the upper region of the stack structure 410 as the peripheral circuit region. In addition, by operating a cell array using the peripheral circuit PC and the second transistor 480, it is possible to improve the performance of the semiconductor device.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the scope of the present disclosure, and it should be construed that these substitutions, modifications, and changes belong to the scope of the present disclosure.

What is claimed is:

1. A semiconductor device comprising:
a peripheral circuit located on a substrate;
a stack structure located over the peripheral circuit in a non-core region and including insulating layers and dummy layers that are alternately and repeatedly stacked;
a channel pattern located on the stack structure;
a transistor located on the channel pattern;
a contact structure extending through the stack structure and electrically connecting the peripheral circuit to the channel pattern;
a gate structure located over the peripheral circuit in a core region and including insulating layers and conductive layers that are alternately and repeatedly stacked;
a first source pattern located on the gate structure; and
a channel structure extending through the gate structure to contact the first source pattern.

2. The semiconductor device of claim 1, wherein the transistor comprises:
a gate electrode located on the channel pattern; and
junctions located in the channel pattern.

3. The semiconductor device of claim 2, wherein the gate electrode includes polysilicon, metal, or a combination thereof.

4. The semiconductor device of claim 2, further comprising a second source pattern located on the first source pattern.

5. The semiconductor device of claim 4, further comprising a contact via connected to at least one of the gate electrode, the junctions, the first source pattern, and the second source pattern.

6. The semiconductor device of claim 4, wherein the second source pattern has substantially a same thickness as the gate electrode.

7. The semiconductor device of claim 1, wherein the contact structure electrically connects the transistor and the peripheral circuit to each other.

8. The semiconductor device of claim 1, further comprising a bonding structure located between the peripheral circuit and the stack structure.

9. The semiconductor device of claim 1, wherein the channel pattern includes a single crystal silicon.

10. A semiconductor device comprising:
a substrate;
a first transistor located on the substrate;
a stack structure located over the first transistor in a non-core region and including insulating layers and dummy layers that are alternately and repeatedly stacked;
a single crystal silicon pattern located on the stack structure;
a second transistor located on the single crystal silicon pattern;
a contact structure extending through the stack structure to contact the single crystal silicon pattern; and
a bonding structure located between the first transistor and the stack structure and electrically connecting the contact structure to the first transistor.

11. The semiconductor device of claim 10, wherein the second transistor comprises:
a gate electrode located on the single crystal silicon pattern; and
junctions located in the single crystal silicon pattern.

12. The semiconductor device of claim 11, wherein the gate electrode includes polysilicon, metal, a combination thereof.

13. The semiconductor device of claim 11, further comprising a contact via connected to at least one of the gate electrode and the junctions.

14. The semiconductor device of claim 10, further comprising:
a gate structure located over the first transistor in the core region and including insulating layers and conductive layers that are alternately and repeatedly stacked;
a first source pattern located on the gate structure; and
a channel structure extending through the gate structure to contact the first source pattern.

15. The semiconductor device of claim 14, further comprising a second source pattern located on the first source pattern.

16. The semiconductor device of claim 15, further comprising a contact via connected to at least one of the first source pattern and the second source pattern.

17. The semiconductor device of claim 15, wherein the second transistor includes a gate electrode which has substantially a same thickness as the second source pattern.

18. A method for manufacturing a semiconductor device, the method comprising:
forming a stack structure on a substrate;
forming a channel structure extending through the stack structure;
forming a contact structure extending through the stack structure to contact the substrate;
forming a preliminary channel layer by removing a portion of the substrate so that the channel structure is exposed;
forming channel patterns by patterning the preliminary channel layer;
forming a conductive layer on the channel patterns; and
forming gate electrodes on the channel patterns, respectively, by patterning the conductive layer.

19. The method of claim 18, further comprising:
forming a first source pattern on the channel structure, the first source pattern being connected to the channel structure; and
forming a second source pattern on the first source pattern by patterning the conductive layer.

20. The method of claim 19, wherein the forming of the first source pattern comprises:
forming a source layer on the channel structure; and
forming the first source pattern by patterning the source layer.

21. The method of claim 20, wherein when the source layer is patterned, the channel patterns are formed by patterning the preliminary channel layer.

22. The method of claim 19, further comprising, after the forming of the preliminary channel layer, forming junctions in the preliminary channel layer.

23. The method of claim 22, further comprising forming a contact via connected to at least one of the gate electrode, the junctions, the first source pattern, and the second source pattern.

24. The method of claim 18, wherein each of the channel patterns is a single crystal silicon pattern.

25. A method for manufacturing a semiconductor device, the method comprising:
forming a first wafer including a first substrate, a peripheral circuit formed on the first substrate, and a first bonding pad formed on the peripheral circuit;
forming a second wafer including a second substrate, a stack structure formed on the second substrate, a contact structure extending through the stack structure to contact the second substrate, a gate structure formed on the second substrate, a channel structure extending into the second substrate through the gate structure, and a second bonding pad formed on the contact structure and the channel structure;
bonding the first wafer and the second wafer so that the first bonding pad and the second bonding pad are electrically connected to each other;
exposing the channel structure and forming a preliminary channel layer connected to the contact structure, by partially removing the second substrate;
forming channel patterns by patterning the preliminary channel layer; and
forming gate electrodes on the channel patterns, respectively.

26. The method of claim 25, further comprising forming a first source pattern on the gate structure, the first source pattern being connected to the channel structure.

27. The method of claim 26, wherein the forming of the first source pattern comprises:
forming a source layer on the channel structure; and
forming the first source pattern by patterning the source layer.

28. The method of claim 27, wherein when the source layer is patterned, the channel patterns are formed by patterning the preliminary channel layer.

29. The method of claim 27, wherein the forming of the gate electrodes comprises:
forming a conductive layer on the channel patterns and the first source pattern; and
forming the gate electrodes on the channel patterns, respectively, by patterning the conductive layer.

30. The method of claim 29, further comprising forming a second source pattern on the first source pattern by patterning the conductive layer.

31. The method of claim 30, further comprising, after the forming of the preliminary channel layer, forming junctions in the preliminary channel layer.

32. The method of claim 31, further comprising forming a contact via connected to at least one of the gate electrode, the junctions, the first source pattern, and the second source pattern.

33. The manufacturing method of claim 25, wherein the channel patterns include a single crystal silicon.
